(19) United States
(12) Patent Application Publication
(10) Pub. No.: US 2016/0202518 A1
(43) Pub. Date: Jul. 14, 2016

(54) LIQUID CRYSTAL DISPLAY AND MANUFACTURING METHOD THEREOF

(71) Applicant: Samsung Display Co., Ltd., Yongin-si (KR)

(72) Inventors: Seong Gyu KWON, Suwon-si (KR); Jae Cheol PARK, Hwaseong-si (KR); Dae Ho SONG, Hwaseong-si (KR); You Young JIN, Suwon-si (KR)

(21) Appl. No.: 14/932,639

(22) Filed: Nov. 4, 2015

(30) Foreign Application Priority Data
Jan. 9, 2015 (KR) 10-2015-0003677

(51) Int. Cl. G02F 1/1341; H01L 27/12; G02F 1/1335; G02F 1/1362; G02F 1/1368; G02F 1/1333

(52) U.S. Cl. CPC G02F 1/1341; G02F 1/1368; G02F 1/133377; G02F 1/133512; G02F 1/136286; H01L 27/1259

(57) ABSTRACT

A liquid crystal display is provided. The liquid crystal display includes: a substrate; a thin film transistor disposed on the substrate; a pixel electrode disposed on the thin film transistor; a roof layer facing the pixel electrode; and partition walls forming a plurality of microcavities between the pixel electrode and the roof layer, wherein the plurality of microcavities include liquid crystal molecules, and the partition walls include light blocking, materials.

### CROSS-REFERENCE TO RELATED APPLICATION

This application claims priority to and the benefit of Korean Patent Application No. 10-2015-0003677 filed in the Korean Intellectual Property Office on Jan. 9, 2015, the entire contents of which are incorporated herein by reference.

### BACKGROUND

(a) Field

The present application relates to a liquid crystal display and a manufacturing method thereof.

(b) Description of the Related Art

A liquid crystal display, which is one of flat panel display devices that are currently used widely, includes two display panels on which electric field generating electrodes such as a pixel electrode, a common electrode, and the like, are formed, and a liquid crystal layer interposed between the two display panels.

A voltage is applied to the electric field generating electrodes to generate an electric field in the liquid crystal layer, thereby determining alignment of liquid crystal molecules of the liquid crystal layer and controlling polarization of incident light to display an image.

As one of the liquid crystal displays, a technology of implementing a display by forming a plurality of microcavities in pixels and filling the microcavities with liquid crystal molecules has been developed. In a liquid crystal display according to the related art, two substrates have been used. In this technology, components may be formed on one substrate to decrease a weight, a thickness, and the like, of the liquid crystal display.

In the display device in which the plurality of microcavities are formed, a roof layer is formed in order to maintain the microcavities. The roof layer may be continuously connected between microcavities neighboring to each other to form a partition wall in a region overlapped with a signal line. Since this partition wall has a width larger than that of the signal line, it may decrease an aperture ratio.

The above information disclosed in this Background section is only for enhancement of understanding of the background and therefore it may contain information that does not form the prior art that is already known in this country to a person of ordinary skill in the art.

### SUMMARY

Embodiments have been made in an effort to provide a liquid crystal display and a manufacturing method thereof having features of an improved aperture ratio.

An exemplary embodiment provides a liquid crystal display including: a substrate; a thin film transistor disposed on the substrate; a pixel electrode disposed on the thin film transistor; a roof layer facing the pixel electrode; and partition walls forming a plurality of microcavities between the pixel electrode and the roof layer, wherein the plurality of microcavities include liquid crystal molecules, and the partition walls include light blocking materials.

The liquid crystal display may further include an inlet of the microcavity formed between the partition wall and the roof layer.

The partition walls may include horizontal partition walls that are in parallel with gate lines connected to the thin film transistor and vertical partition walls that are in parallel with data lines connected to the thin film transistor.

The inlet may be formed by opening a portion of the roof layer adjacent to the horizontal partition wall.

The inlet may have a shape in which the inlets is lengthily extended along the horizontal partition wall.

The inlet may be disposed adjacently to a portion at which the horizontal partition wall and the vertical partition wall meet each other.

The inlet may include a plurality of regions having a shape in which the regions are lengthily extended along the horizontal partition walls or the vertical partition wall at a portion corresponding to one of the plurality of microcavities.

When the respective pixels enclosing an intersection region of the gate line and the data line are a first pixel, a second pixel, a third pixel, and a fourth pixel, the inlets may be disposed adjacently to the intersection region in the respective pixels.

The liquid crystal display may further include a common electrode disposed below the roof layer and facing the pixel electrode based on the plurality of microcavities.

The inlet may simultaneously penetrate through the roof layer and the common electrode.

A partition wall of the partition walls forming one microcavity of the plurality of microcavities may be isolated from a partition wall of the partition walls of another microcavity of the plurality of microcavities neighboring to the one microcavity in a direction in which the gate lines are extended.

The horizontal partition walls may include a groove structure.

The inlets may be disposed in a portion overlapped with the partition walls.

The inlets may be disposed between the roof layer and the horizontal partition walls.

The horizontal partition wall may cover the thin film transistor.

The liquid crystal display may further include a capping layer disposed on the roof layer, wherein the capping layer covers the inlet.

Another exemplary embodiment provides a manufacturing method of a liquid crystal display, including: forming a thin film transistor on a substrate; forming a pixel electrode on the thin film transistor; forming a light blocking material layer on the pixel electrode; exposing a preliminary partition wall region of the light blocking material layer; forming a roof material layer on the light blocking material layer; patterning the roof material layer by a photo process to form a roof layer; and developing the exposed light blocking material layer to form partition walls, wherein the partition walls form a plurality of microcavities between the pixel electrode and the roof layer.

The manufacturing method of a liquid crystal display may further include forming inlets of the plurality of microcavities between the partition walls and the roof layer.

The light blocking material layer may have negative photo characteristics.

Exposure wavelengths in the exposing of the preliminary partition wall region and in the patterning of the roof material layer by the photo process to form the roof layer may be different from each other.

As set forth above, according to exemplary embodiments, the partition walls including the light blocking materials are used to form the plurality of microcavities, thereby making it possible to simplify a process.

In addition, the common electrodes disposed on the side walls of the partition walls are removed in the display device in which the plurality of microcavities are formed, thereby making it possible to prevent a short-circuit between the common electrode and the pixel electrodes and improve an aperture ratio.

### BRIEF DESCRIPTION OF THE DRAWINGS

FIG. 1 is a plan view showing a liquid crystal display according to an exemplary embodiment.

FIG. 2 is a cross-sectional view taken along line II-II of FIG. 1.

FIG. 3 is a cross-sectional view taken along line III-III of FIG. 1.

FIG. 4 is a perspective view showing a partition wall according to an exemplary embodiment of FIGS. 1 to 3.

FIGS. 5, 6, and 7 are perspective views showing modified exemplary embodiments of the partition wall of FIG. 4.

FIG. 8 is a cross-sectional view of the liquid crystal display including the partition wall according to an exemplary embodiment of FIG. 7, taken along line II-II of FIG. 1.

FIG. 9 is a perspective view showing the partition wall and a roof layer according to an exemplary embodiment of FIGS. 1 to 3.

FIGS. 10, 11, 12, 13, 14, and 15 are perspective views showing modified exemplary embodiments of the roof layer of FIG. 9.

FIGS. 16, 17, 18, and 19 are cross-sectional views showing a manufacturing method of a liquid crystal display according to an exemplary embodiment.

### DETAILED DESCRIPTION OF THE EMBODIMENTS

Exemplary embodiments will be described in detail with reference to the accompanying drawings. However, the inventive concept is not limited to exemplary embodiments described therein, but may also be embodied in other forms. On the contrary, exemplary embodiments introduced herein are provided to make disclosed contents thorough and complete and sufficiently transfer the spirit of the inventive concept to those skilled in the art.

In the accompanying drawings, thickness of layers and regions may be exaggerated for clarity. In addition, it will be understood that when a layer is referred to as being “on” another layer or substrate, the layer can be directly formed on another layer or substrate or other layer(s) may also be interposed therebetween. Like reference numerals designate like elements throughout the specification.

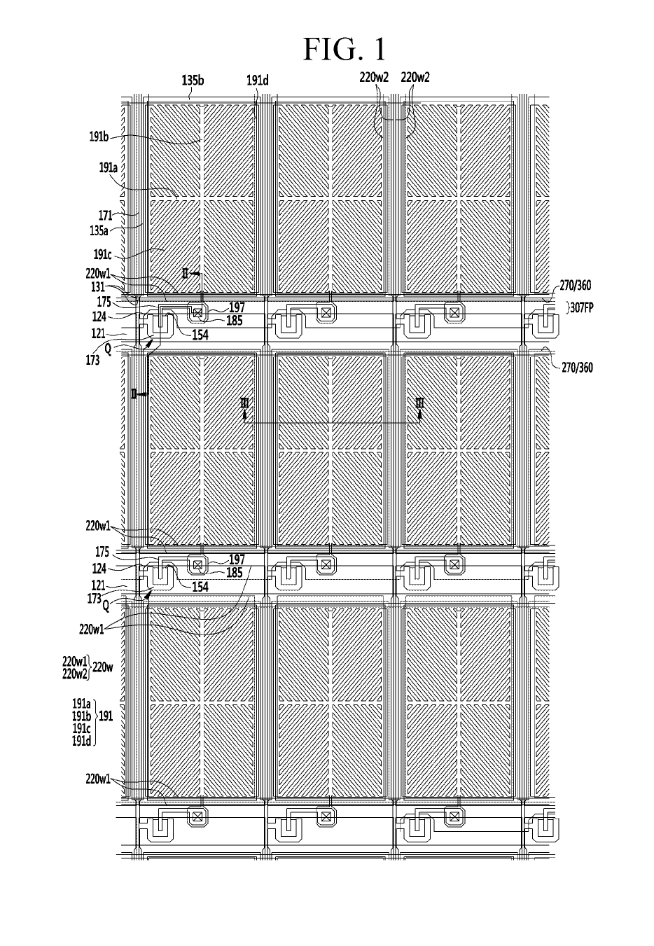

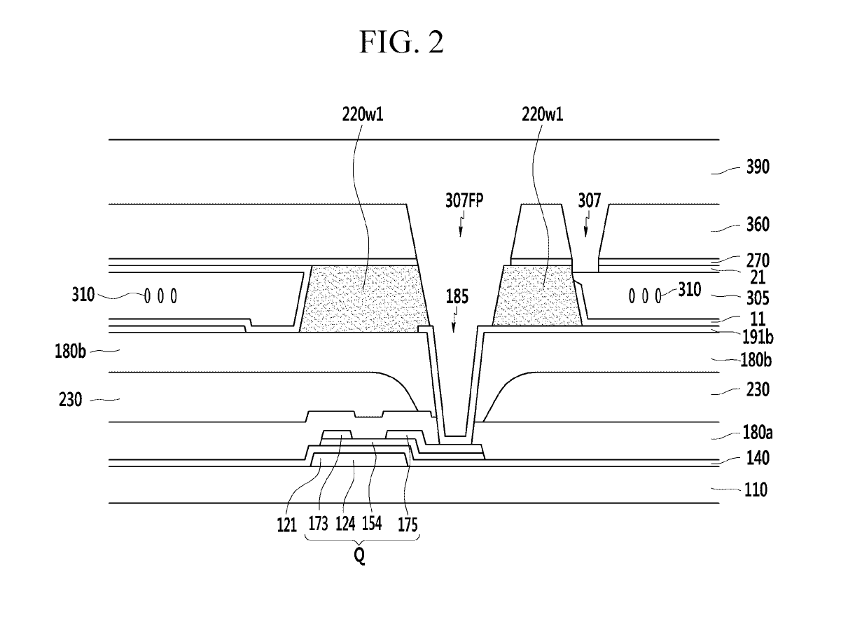

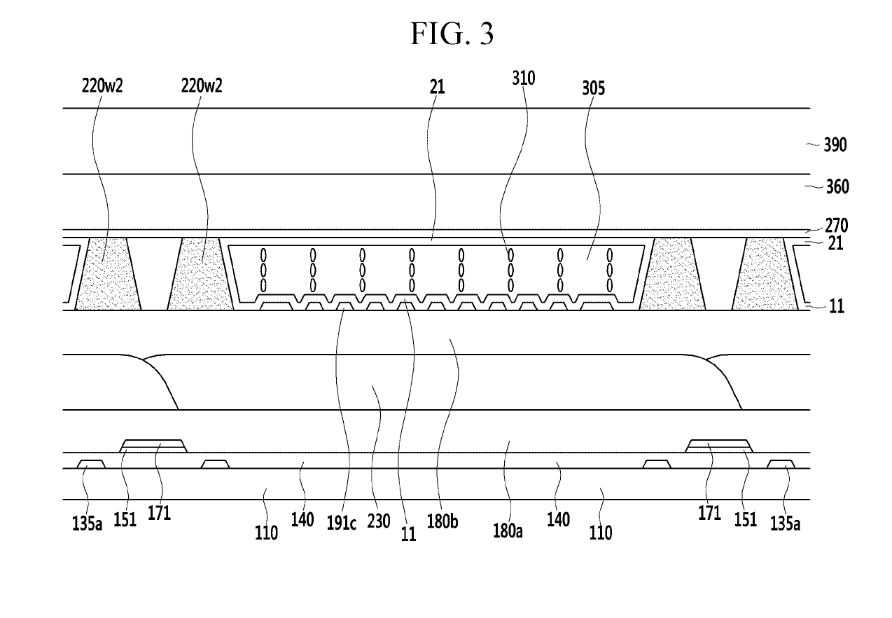

FIG. 1 is a plan view showing a liquid crystal display according to an exemplary embodiment. FIG. 2 is a cross-sectional view taken along line II-II of FIG. 1. FIG. 3 is a cross-sectional view taken along line III-III of FIG. 1. FIG. 1 shows 3*3 pixel portions, which are some of a plurality of pixels corresponding to a plurality of microcavities 305, respectively. In a liquid crystal display according to an exemplary embodiment, these pixels may be repeatedly arranged in all directions.

Referring to FIGS. 1 to 3, gate lines 121 and storage electrode lines 131 are formed on a substrate 110 formed of transparent glass, plastic, or the like. The gate lines 121 include gate electrodes 124. The storage electrode lines 131 are mainly extended in a horizontal direction and transfer a predetermined voltage such as a common voltage Vcom, or the like. The storage electrode line 131 includes a pair of vertical parts 135a extended substantially vertically to the gate line 121 and a horizontal part 135b connecting ends of the pair of vertical parts 135a to each other. Storage electrodes 135a and 135b have a structure in which they enclose a pixel electrode 191.

A gate insulating layer 140 is formed on the gate lines 121 and the storage electrode lines 131. A semiconductor layer 151 disposed below data lines 171 and a semiconductor layer 154 disposed below source/drain electrodes 173/175 and in a channel portion of a thin film transistor Q are formed on the gate insulating layer 140.

A plurality of ohmic contact members (not shown) may be formed on the respective semiconductor layers 151 and 154 and between the data lines 171 and the source/drain electrodes 173/175.

Data conductors 171, 173, and 175 including a source electrode 173, the data line 171 connected to the source electrode 173, and a drain electrode 175 are formed on the respective semiconductor layers 151 and 154 and the gate insulating layer 140.

The gate electrode 124, the source electrode 173, and the drain electrode 175 form the thin film transistor Q together with the semiconductor layer 154, and a channel of the thin film transistor Q is formed in a portion of the semiconductor layer 154 between the source electrode 173 and the drain electrode 175.

A first interlayer insulating layer 180a is formed on the data conductors 171, 173, and 175 and the exposed portion of the semiconductor layer 154. The first interlayer insulating layer 180a may include an inorganic insulator or an organic insulator such as silicon nitride (SiNx), silicon oxide (SiOx), or the like.

A color filter 230 is formed on the first interlayer insulating layer 180a.

The color filter 230 may display one of primary colors such as three primary colors including a red, a green, and a blue. However, the color filter 230 is not limited to displaying the three primary colors including the red, the green, and the blue, but may also display one of a cyan, a magenta, a yellow, and a white. The color filters 230 may be formed of materials displaying different colors for each of adjacent pixels.

A second interlayer insulating layer 180b covering the color filter 230 is formed on the color filter 230. The second interlayer insulating layer 180b may include an inorganic insulator or an organic insulator such as silicon nitride (SiNx), silicon oxide (SiOx), or the like.

In the case in which neighboring color filters 230 are overlapped with each other, such that a step is generated, the second interlayer insulating layer 180b may include an organic insulator to decrease or remove the step.

A contact hole 185 extending to and exposing the drain electrode 175 is formed in the color filter 230 and the interlayer insulating layers 180a and 180b.

The pixel electrode 191 is disposed on the second interlayer insulating layer 180b. The pixel electrode 191 may be formed of a transparent conductive material such as ITO, IZO, or the like.

The pixel electrode 191 generally has a rectangular shape, and includes a cross stem part including a horizontal stem part 191a and a vertical stem part 191b intersecting with the horizontal stem part 191a. In addition, the pixel electrode 191 is divided into four sub-regions by the horizontal stem part 191a and the vertical stem part 191b, wherein each of the sub-regions includes a plurality of fine branch parts 191c. In addition, in the present exemplary embodiment, the pixel electrode 191 may further include outer side stem parts 191d connecting the fine branch parts 191c to each other at left and right outer sides thereof. In the present exemplary embodiment, the outer side stem parts 191d may be disposed at the left and right outer sides of the pixel electrode 191 or be disposed so as to be extended up to an upper portion or a lower portion of the pixel electrode 191.

The fine branch parts 191c of the pixel electrode 191 form an angle of approximately 40 to 45 degrees with respect to the gate line 121 or the horizontal stem part 191a. In addition, the fine branch parts 191c of two neighboring sub-regions may he orthogonal to each other. In addition, widths of the fine branch parts 191c may become gradually wide or intervals between the fine branch parts 191c may be different from each other.

The pixel electrode 191 includes an extension part 197 connected thereto at a lower end of the vertical stem part 191b and having an area wider than that of the vertical stem part 191b. The pixel electrode 191 is physically and electrically connected to the drain electrode 175 through the contact hole 185 at the extension part 197, and receives a data voltage applied from the drain electrode 175.

A description for the thin film transistor Q and the pixel electrode 191 stated hereinabove are only an example, and a structure of the film transistor Q and a design of the pixel electrode 191 are not limited to the structures described in the present exemplary embodiment, but may be modified in order to improve side visibility, thereby applying contents according to an exemplary embodiment.

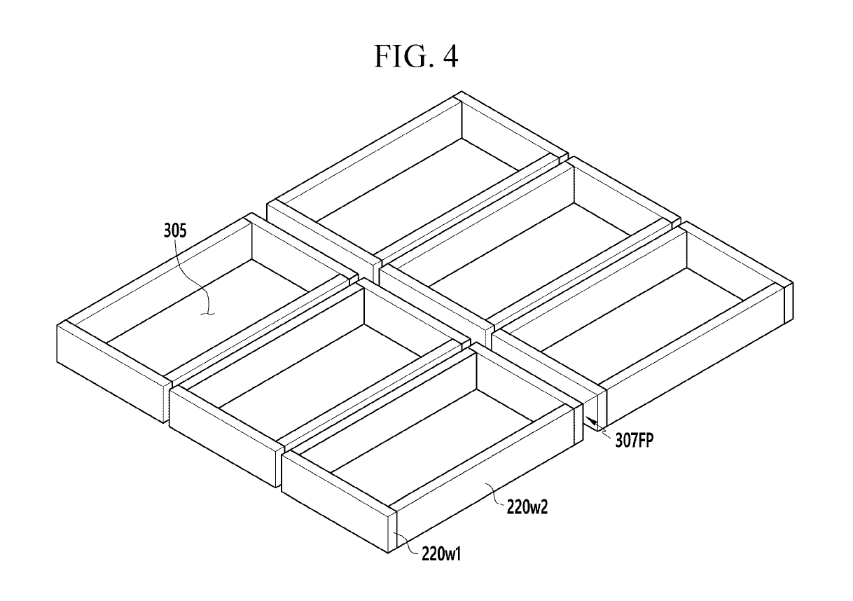

Next, a partition wall 220w according to the present exemplary embodiment will be described with reference to FIGS. 1 to 4. FIG. 4 is a perspective view showing a partition wall 220w according to an exemplary embodiment of FIGS. 1 to 3.

Referring to FIGS. 1 to 4, partition walls 220w are formed on the pixel electrode 191 and the second interlayer insulating layer 180b. In the liquid crystal display according to an exemplary embodiment, liquid crystal layers including liquid crystal materials 310 are formed in the plurality of microcavities 305. The partition walls 220w may partition the respective microcavities 305. The partition walls 220w include horizontal partition walls 220w1 extended substantially in parallel with the gate lines 121 and vertical partition walls 220w2 extended substantially in parallel with the data lines 171. In the present exemplary embodiment, the partition wall 220w is formed of a light blocking material that may block light. As the light blocking material, a material generally used in a black matrix in the liquid crystal display in order to absorb external light reflection and improve a contrast ratio may be used.

In the present exemplary embodiment, a partition wall 220w forming one microcavity 305 is isolated from a partition wall 220w of another microcavity 305 neighboring to the one microcavity 305 in a direction in which the gate lines 121 are extended. In addition, the partition wall 220w forming one microcavity 305 may be isolated from a partition wall 220w of another microcavity 305 neighboring to the one microcavity 305 in a direction in which the data lines 171 are extended. Here, a trench 307FP may be formed in the direction of the gate line 121.

In the present exemplary embodiment, the horizontal partition wall 220w1 covers the thin film transistor Q, as shown in FIG. 1. The horizontal partition wall 220w1 prevents generation of a light leakage current due to irradiation of light to the thin film transistor Q. The vertical partition wall 220w2 may be overlapped with one of two sides of the data line 171 that are in parallel with each other.

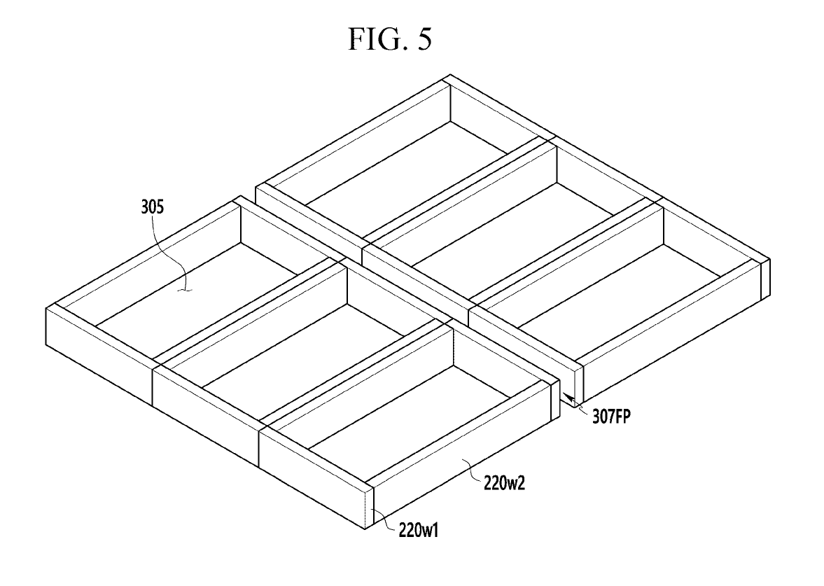

Next, various partition walls 220w according to modified exemplary embodiments will be described with reference to FIGS. 5 to 8. Partition walls are not limited to partition walls 220w to be described below, but may be variously modified as long as they may be appropriate for features of the inventive concept.

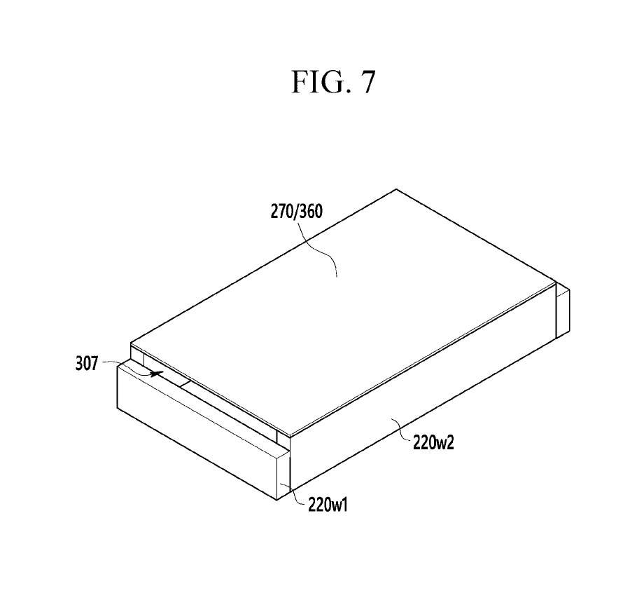

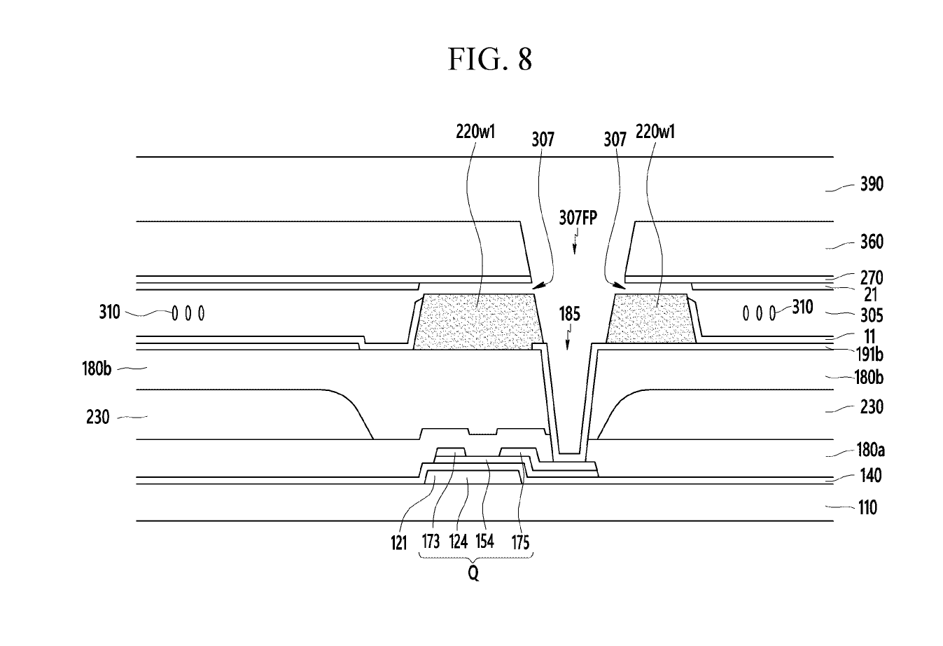

FIGS. 5 to 7 are perspective views showing modified exemplary embodiments of the partition wall of FIG. 4. FIG. 8 is a cross-sectional view of the liquid crystal display including the partition wall according to an exemplary embodiment of FIG. 7, taken along line II-II of FIG. 1.

Referring to FIG. 5, horizontal partition walls 220w1 according to the present exemplary embodiment are not isolated from each other in the direction in which the gate lines 121 are extended, but may be connected to each other in the direction in which the gate lines 121 are extended. Contents described with reference to FIG. 4 except for this difference may be applied to the present exemplary embodiment.

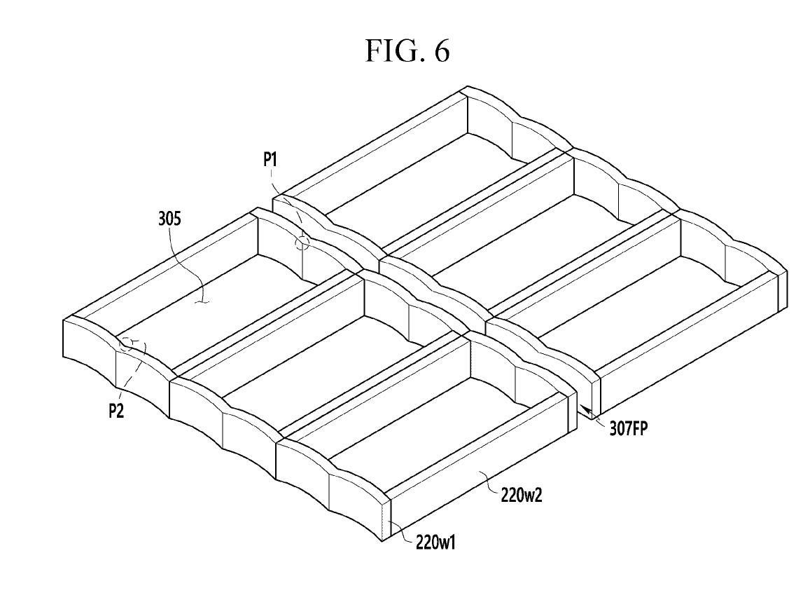

Referring to FIG. 6, horizontal partition walls 220w1 are not isolated from each other in the direction in which the gate lines 121 are extended, but may be connected to each other in the direction in which the gate lines 121 are extended, similar to the horizontal partition walls described with reference to FIG. 5. The horizontal partition walls 220w1 include groove structures P1 and P2 unlike an exemplary embodiment of FIG. 5. The groove structures P1 and P2 may include a first groove P1 protruding from the horizontal partition wall 220w1 toward the microcavity 305 and a second groove P2 protruding in a direction in which it becomes distant from, i.e., away from, the microcavity 305. Contents described with reference to FIG. 4 except for the difference described above may be applied to the present exemplary embodiment.

Referring to FIGS. 7 and 8, the horizontal partition wall 220w1 according to the present exemplary embodiment may have a height lower than that of the vertical partition wall 220w2. Here, a common electrode 270 and a roof layer 360 formed on the partition wall 220w may cover an upper surface of the horizontal partition wall 220w1. In the present exemplary embodiment, an inlet 307 is formed between the upper surface of the horizontal partition wall 220w1 and the common electrode 270/the roof layer 360, such that the liquid crystal materials 310 may be injected in the horizontal direction. Contents described with reference to FIG. 4 except for the difference described above may be applied to the present exemplary embodiment.

Again referring to FIGS. 1 to 3, a lower alignment layer 11, which may be a vertical alignment layer, is formed on the pixel electrode 191. The lower alignment layer 11, which is a liquid crystal alignment layer formed of polyamic acid, polysiloxane, polyimide, or the like, may include at least one of generally used materials.

An upper alignment layer 21 is disposed at a portion facing the lower alignment layer 11, and the microcavity 305 is formed between the lower alignment layer 11 and the upper alignment layer 21. The liquid crystal materials 310 including liquid crystal molecules are injected into the microcavity 305, and the microcavity 305 has the inlet 307, as shown in FIG. 2. The inlet 307 is disposed between the partition wall 220w and the roof layer 360. In the present exemplary embodiment, the inlet 307 may be disposed in a region overlapped with the horizontal partition wall 220w1 and he formed at a position close to a central portion of the horizontal partition wall 220w1. A detailed description for the inlet 307 will be provided later.

The plurality of microcavities 305 may be formed in a column direction of the pixel electrode 191, in other words, in a vertical direction. In the present exemplary embodiment, the liquid crystal materials 310 including alignment materials forming the alignment layers 11 and 21 and the liquid crystal molecules may be injected into the microcavities 305 by capillary force. In the present exemplary embodiment, the lower alignment layer 11 and the upper alignment layer 21 are only distinguished from each other depending on their positions, and may be connected to each other, as shown in FIG. 3. The lower alignment layer 11 and the upper alignment layer 21 may be simultaneously formed.

The microcavity 305 is divided in the vertical direction by the horizontal partition walls 220w1 or a plurality of trenches 307FP disposed at portions overlapped with the gate line 121, such that the plurality of microcavities 305 are formed. Here, the plurality of microcavities 305 may be formed in the column direction of the pixel electrode 191, in other words, the vertical direction. In addition, the microcavity 305 is divided in the horizontal direction by the vertical partition walls 220w2, such that a plurality of microcavities 305 are formed. Here, the plurality of microcavities 305 may be formed in a row direction of the pixel electrode 191, in other words, in the horizontal direction in which the gate line 121 is extended. Each of the plurality of microcavities 305 may correspond to one or two or more pixel areas, which may correspond to areas in which a screen is displayed.

The common electrode 270 and the roof layer 360 are disposed on the upper alignment layer 21. The common electrode 270 receives a common voltage applied thereto and generates an electric field together with the pixel electrode 191 to which the data voltage is applied to determine a direction in which the liquid crystal materials 310 disposed in the microcavity 305 between the two electrodes are inclined. The common electrode 270 forms a capacitor together with the pixel electrode 191 to maintain the applied voltage even after the thin film transistor is turned off.

Although the case in which the common electrode 270 is formed at a position facing the pixel electrode 191 based on the microcavity 305 has been described in the present exemplary embodiment, the common electrode 270 may be formed together with the pixel electrode 191 below the microcavity 305 to drive a liquid crystal in a horizontal electric field mode, in another exemplary embodiment.

The roof layer 360 serves as a support so that the microcavity 305, which is a cavity between the pixel electrode 191 and the common electrode 270, may be formed. The roof layer 360 is an inorganic insulating layer formed of an inorganic material such as silicon nitride (SiNx) or silicon oxide (SiOx). The roof layer 360 may be formed of a single inorganic layer or be formed of a multilayer inorganic layer. In the case in which the roof layer 360 is formed of the multilayer inorganic layer, the roof layer 360 may be formed by stacking inorganic layers having different stresses.

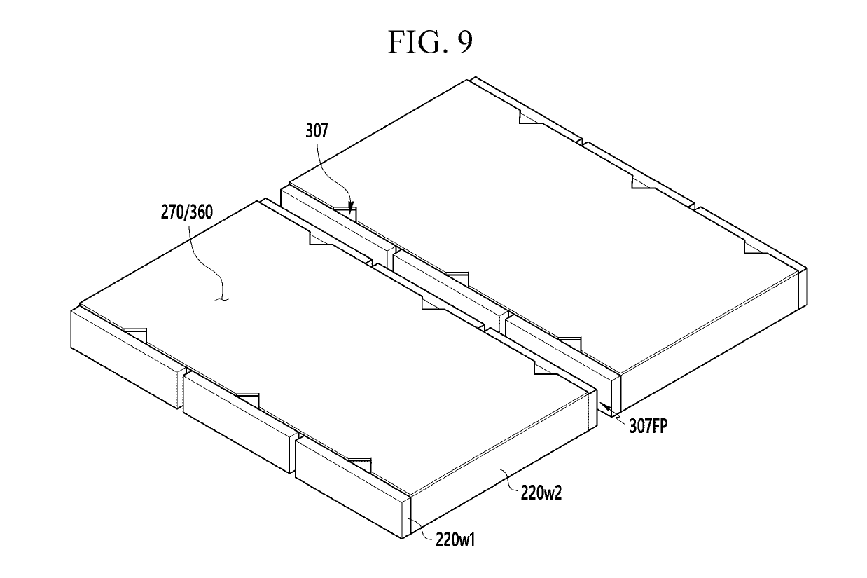

FIG. 9 is a perspective view showing the partition wall and a roof layer according to an exemplary embodiment of FIGS. 1 to 3.

Referring to FIG. 9, in the present exemplary embodiment, the inlets 307 may be formed while simultaneously penetrating through the common electrode 270 and the roof layer 360. The number of inlets 307 formed in each microcavity 305 may be at least one. The inlet 307 may be formed by opening portions of the common electrode 270 and the roof layer 360 adjacent to the horizontal partition wall 220w1.

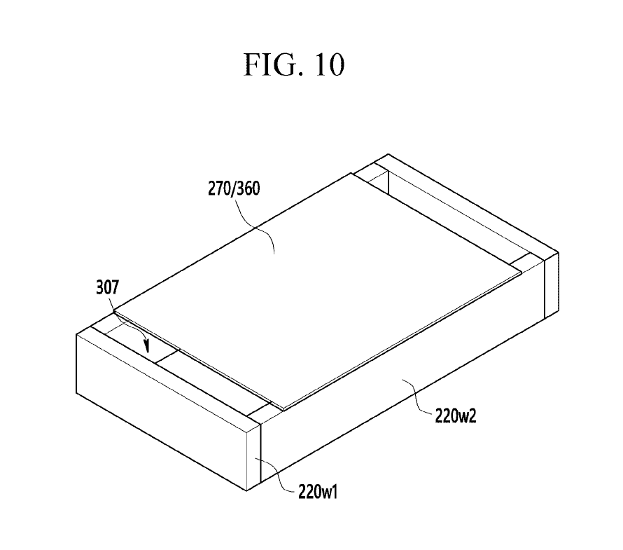

Next, various structures of a common electrode 270 and a roof layer 360 according to modified exemplary embodiments will be described with reference to FIGS. 10 to 15. A common electrode 270 and a roof layer 360 are not limited to having structures to be described below, but may be variously modified as long as they may be appropriate for features of the inventive concept.

FIGS. 10 to 15 are perspective views showing modified exemplary embodiments of the roof layer of FIG. 9.

Referring to FIG. 10, a common electrode 270 and a roof layer 360 according to the present exemplary embodiment may have an inlet 307 having a shape in which it is lengthily extended along the horizontal partition wall 220w1. Here, the inlet 307 may be formed in parallel with the horizontal partition wall 220w1 at a position adjacent to the horizontal partition wall 220w1.

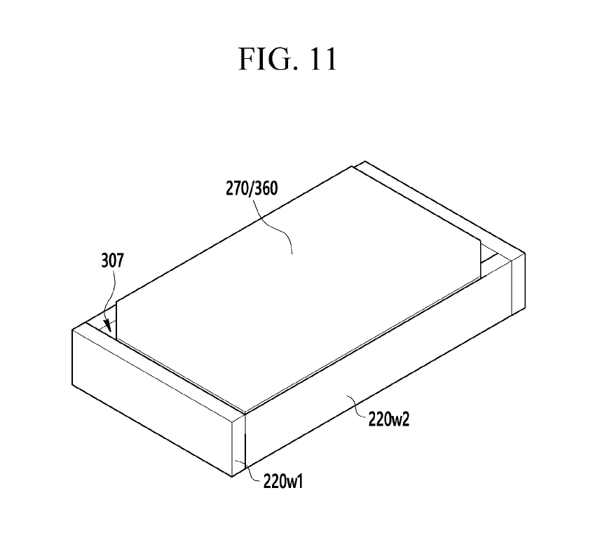

Referring to FIG. 11, a common electrode 270 and a roof layer 360 according to the present exemplary embodiment may have an inlet 307 formed adjacently to a portion at which the horizontal partition wall 220w1 and the vertical partition wall 220w2 meet each other.

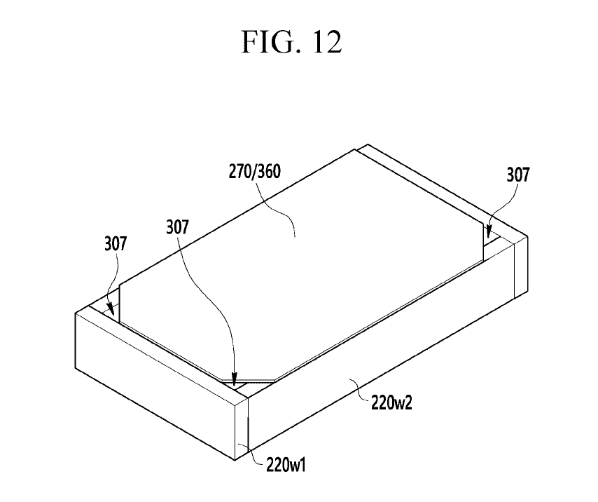

Referring to FIG. 12, a common electrode 270 and a roof layer 360 according to the present exemplary embodiment may have three inlets 307 formed in the partition wall 220w corresponding to one microcavity 305. Here, the numbers of inlets 307 formed adjacently to each of two horizontal partition walls 220w1 partitioning one microcavity 305 and facing each other are different from each other.

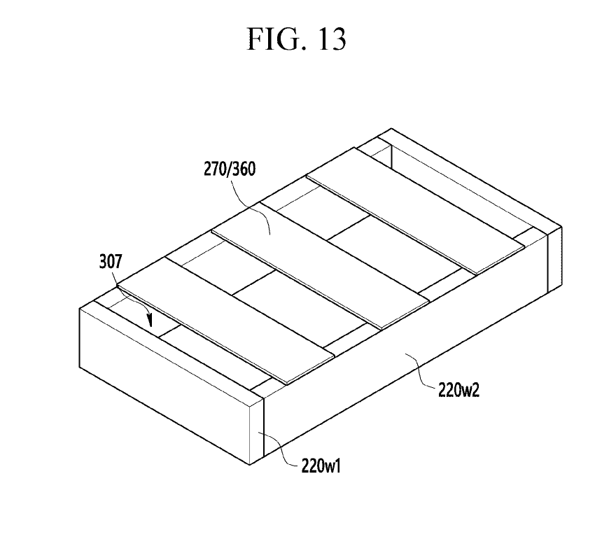

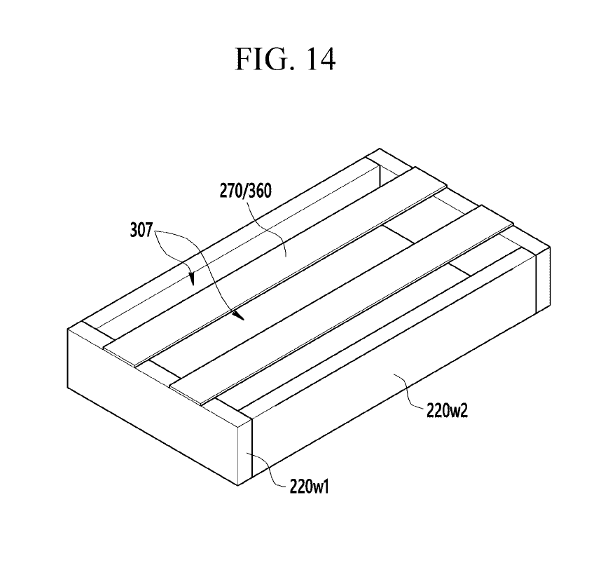

Referring to FIGS. 13 and 14, a common electrode 270 and a roof layer 360 according to the present exemplary embodiment may have an inlet 307 having a shape in which it is lengthily extended along the horizontal partition wall 220w1 or the vertical partition wall 220w2.

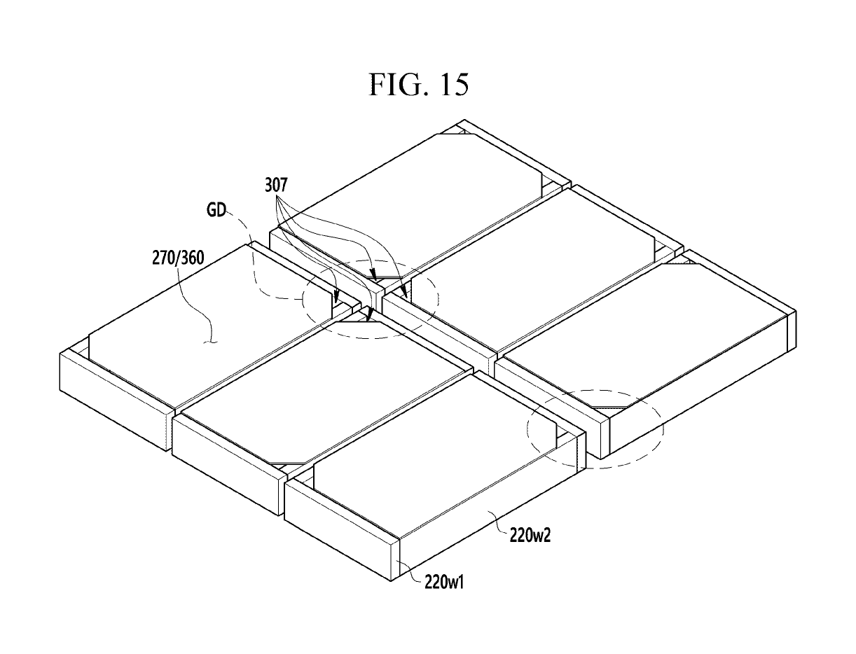

Referring to FIGS. 1 and 15, common electrodes 270 and roof layers 360 according to the present exemplary embodiment may have inlets 307 formed adjacently to portions at which the horizontal partition walls 220w1 and the vertical partition walls 220w2 meet each other, similar to an exemplary embodiment described with reference to FIG. 11. Additionally, when the respective pixels enclosing an intersection region GD of the gate line 121 and the data line 171 are a first pixel, a second pixel, a third pixel, and a fourth pixel, the inlets 307 may be formed adjacently to the intersection region GD in the respective pixels.

Again referring to FIGS. 1 to 3, a capping layer 390 is disposed on the roof layer 360. The capping layer 390 includes an organic material or an inorganic material. In the present exemplary embodiment, the capping layer 390 may be formed in the trench 307FP as well as on the roof layer 360. Here, the capping layer 390 may cover the inlet 307 of the exposed microcavity 305. Although the case in which the liquid crystal materials 310 are removed in the inlet 307 has been shown in the present exemplary embodiment, the liquid crystal materials 310 remaining after being injected into the microcavity 305 may also remain in the inlet 307.

In the present exemplary embodiment, as shown in FIG. 3, since the liquid crystal display has a structure in which the vertical partition walls 220w2 are spaced apart from each other between the microcavities 305 neighboring to each other in the horizontal direction, it may be used appropriately for a curved display device.

In addition, in the present exemplary embodiment, since the partition walls 220w are formed between the microcavities 305, even though the substrate 110 is bent, stress may be less generated, and a change degree of a cell cap may be decreased.

Although not shown, a polarizer may be formed on outer surfaces of the substrate 110 and the capping layer 390.

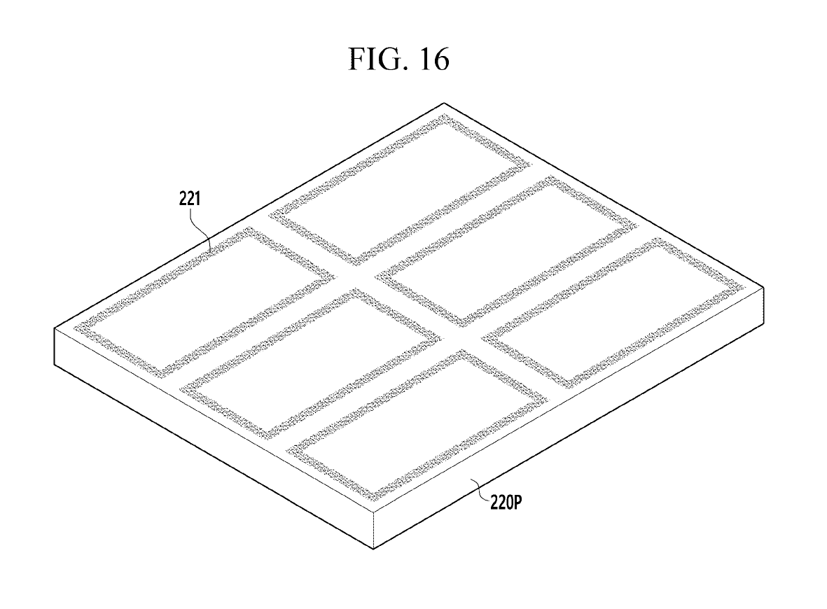

Next, an exemplary embodiment of manufacturing the liquid crystal display described above will be described with reference to FIGS. 16 to 19. An exemplary embodiment to be described below, which is an exemplary embodiment of a manufacturing method, may be modified into another form.

FIGS. 16 to 19 are cross-sectional views showing a manufacturing method of a liquid crystal display according to an exemplary embodiment.

Referring to FIGS. 1, 2, 3, and 16, in order to form a generally known switching element on the substrate 110, the gate lines 121 extended in the horizontal direction are formed, the gate insulating layer 140 is formed on the gate lines 121, the semiconductor layers 151 and 154 are formed on the gate insulating layer 140, and the source electrode 173 and the drain electrode 175 are formed. Here, the data lines 171 connected to the source electrode 173 may be formed so as to be extended in the vertical direction while intersecting with the gate lines 121.

The first interlayer insulating layer 180a is formed on the data conductors 171, 173, and 175 including the source electrode 173, the drain electrode 175, and the data line 171 and the exposed portion of the semiconductor layer 154.

The color filter 230 is formed at a position correspond to the pixel area on the first interlayer insulating layer 180a.

The second interlayer insulating layer 180b covering the color filter 230 is formed. Here, the second interlayer insulating layer 180b is formed so as to have the contact hole 185 electrically and physically connecting the pixel electrode 191 and the drain electrode 175 to each other.

Then, the pixel electrode 191 is formed on the second interlayer insulating layer 180b, and a light blocking material layer 220p is formed on the pixel electrode 191. Light is irradiated to the light blocking material layer 220p, as an exposure step of a photo process. Here, regions to which the light is irradiated are preliminary partition wall regions 221 that will become the partition walls 220w in a final structure.

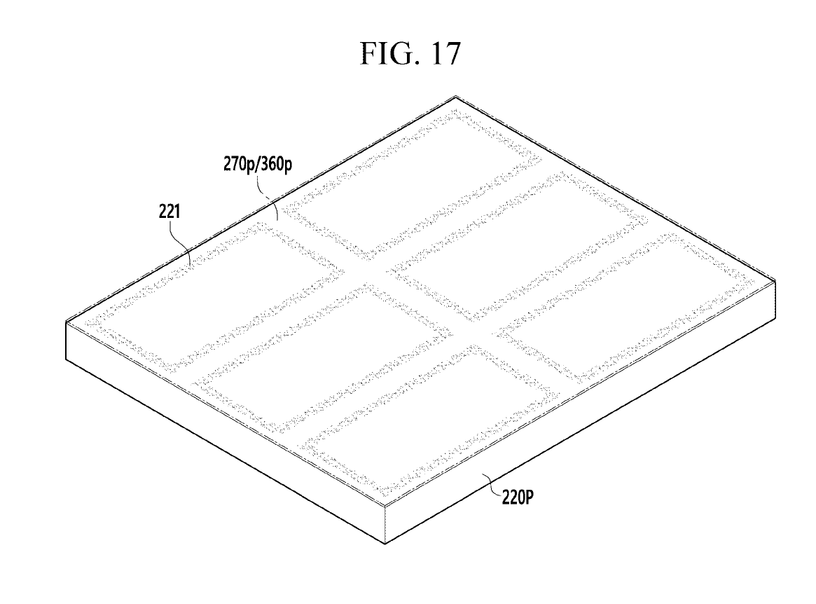

Referring to FIG. 17, a common electrode material layer 270p and a roof material layer 360p are sequentially formed on the light blocking material layer 220p.

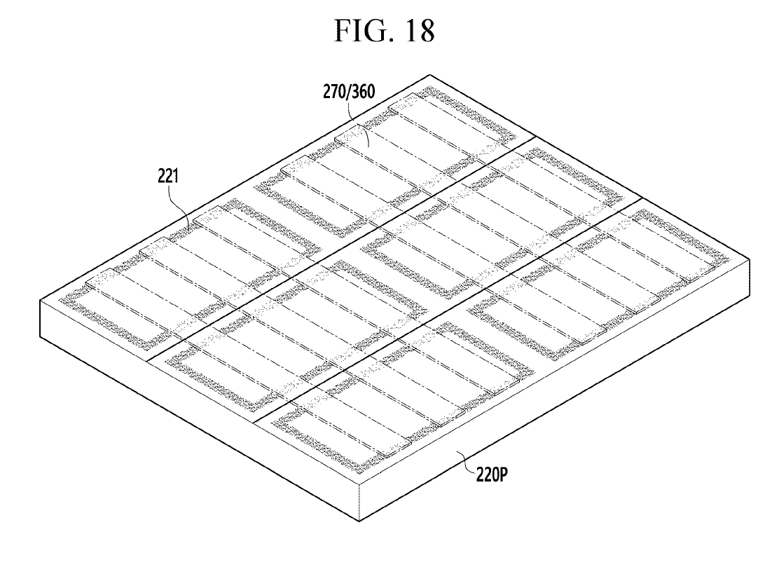

Referring to FIG. 18, the common electrode material layer 270p and the roof material layer 360p may be patterned by a photo process to form the common electrode 270 and the roof layer 360. Here, a light wavelength in an exposure step of the photo process is different from a light wavelength when exposing the preliminary partition wall regions 221 described above. For example, the light wavelength at which the preliminary partition wall regions 221 are exposed may be approximately 365 nanometers, and the light wavelength at which the common electrode material layer 270p and the roof material layer 360p are exposed may be approximately 400 nanometers or more. This is to allow the light blocking material layer 220p not to be removed in a process of patterning the common electrode material layer 270p and the roof material layer 360p.

Although the structures of the common electrode 270 and the roof layer 360 described with reference to FIG. 13 have been shown by way of example in FIG. 18, the embodiments are not limited thereto. That is, the common electrode 270 and the roof layer 360 may be formed in various structures, as described above, depending on a change in a mask design of the photo process.

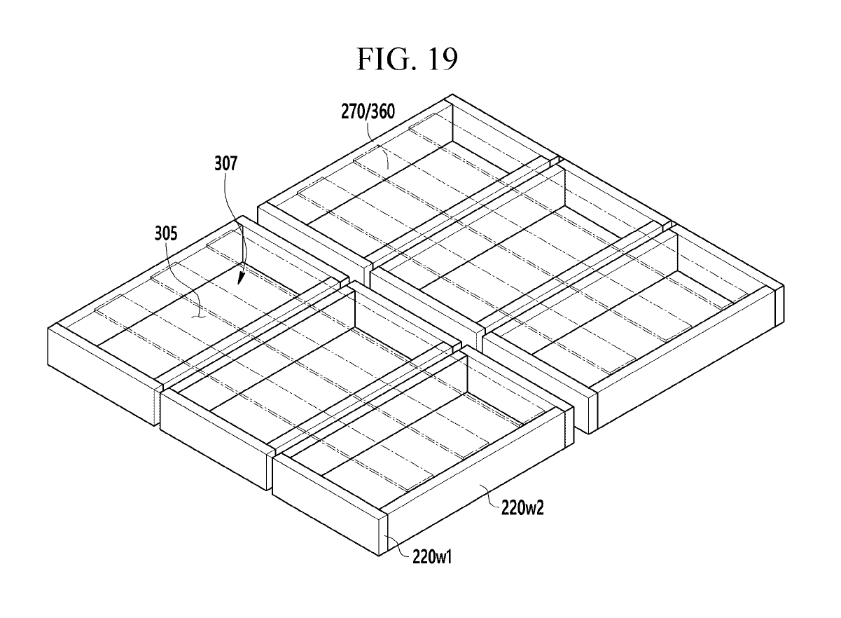

Referring to FIG. 19, the light blocking material layer 220p that is already exposed is developed through a developer. In this case, the light blocking material layer 220p that is not exposed is removed, such that the microcavities 305, the horizontal partition walls 220w1, and the vertical partition walls 220w2 are formed.

Then, the alignment materials are injected through the inlets 307 to form the alignment layers 11 and 21 shown in FIGS. 2 and 3 on the pixel electrode 191 and the common electrode 270. In detail, after the alignment materials including solid contents and solvents are injected through the inlets 307, a bake process is performed.

Next, the liquid crystal materials 310 may be injected into the inlets 307 using an inkjet method, or the like. In this case, the liquid crystal materials 310 including the liquid crystal molecules may enter the microcavities 305 through the inlets 307 by a capillary phenomenon, or the like.

Then, when the capping layer 390 is formed on the roof layer 360 so as to cover the inlets 307 and the trenches 307FP, the liquid crystal display as shown in FIGS. 1 to 3 may be formed.

While the inventive concept has been described in connection with what is presently considered to be practical exemplary embodiments, it is to be understood that the inventive concept is not limited to the disclosed embodiments, but, on the contrary, is intended to cover various modifications and equivalent arrangements included within the spirit and scope of the appended claims.

### DESCRIPTION OF SYMBOLS

| | | | |
|---|---|---|---|
| 220w | partition wall | 270 | common electrode |
| 305 | microcavity | 307 | inlet |
| 360 | roof layer | | |
| 390 | capping layer | | |

What is claimed is:

1. A liquid crystal display comprising:
a substrate;
a thin film transistor disposed on the substrate;
a pixel electrode disposed on the thin film transistor;
a roof layer facing the pixel electrode; and
partition walls forming a plurality of microcavities between the pixel electrode and the roof layer,
wherein the plurality of microcavities comprise liquid crystal molecules, and
the partition walls include light blocking materials.

2. The liquid crystal display of claim 1, further comprising:
an inlet of the microcavity disposed between the partition wall and the roof layer.

3. The liquid crystal display of claim 2, wherein:
the partition walls include horizontal partition walls that are in parallel with gate lines connected to the thin film transistor and vertical partition walls that are in parallel with data lines connected to the thin film transistor.

4. The liquid crystal display of claim 3, wherein:
the inlet is formed by opening a portion of the roof layer adjacent to the horizontal partition wall.

5. The liquid crystal display of claim 4, wherein:
the inlet has a shape in which the inlet is lengthily extended along the horizontal partition wall.

6. The liquid crystal display of claim 5, wherein:
the inlet is disposed adjacently to a portion at which the horizontal partition wall and the vertical partition wall meet each other.

7. The liquid crystal display of claim 3, wherein:
the inlet includes a plurality of regions having a shape in which the regions are lengthily extended along the horizontal partition wall or the vertical partition wall at a portion corresponding to one of the plurality of microcavities.

8. The liquid crystal display of claim 3, wherein:
when the respective pixels enclosing an intersection region of the gate line and the data line are a first pixel, a second pixel, a third pixel, and a fourth pixel, the inlets are disposed adjacently to the intersection region in the respective pixels.

9. The liquid crystal display of claim 4, further comprising:
a common electrode disposed below the roof layer and facing the pixel electrode based on the plurality of microcavities.

10. The liquid crystal display of claim 9, wherein:
the inlet simultaneously penetrates through the roof layer and the common electrode.

11. The liquid crystal display of claim 3, wherein:
a partition wall of the partition walls forming one microcavity of the plurality of microcavities is isolated from a partition wall of the partition walls of another microcavity of the plurality of microcavities neighboring to the one microcavity in a direction in which the gate lines are extended.

12. The liquid crystal display of claim 3, wherein:
the horizontal partition wall comprises a groove structure.

13. The liquid crystal display of claim 3, wherein:
the inlet is disposed in a portion overlapped with the partition wall.

14. The liquid crystal display of claim 13, wherein:
the inlet is disposed between the roof layer and the horizontal partition wall.

15. The liquid crystal display of claim 3, wherein:
the horizontal partition wall covers the thin film transistor.

16. The liquid crystal display of claim 2, further comprising:
a capping layer disposed on the roof layer, wherein the capping layer covers the inlet.

17. A manufacturing method of a liquid crystal display, comprising:
forming a thin film transistor on a substrate;
forming a pixel electrode on the thin film transistor;
forming a light blocking material layer on the pixel electrode;
exposing a preliminary partition wall region of the light blocking material layer;
forming a roof material layer on the light blocking material layer;
patterning the roof material layer by a photo process to form a roof layer; and
developing the exposed light blocking material layer to form partition walls,
wherein the partition walls form a plurality of microcavities between the pixel electrode and the roof layer.

18. The manufacturing method of a liquid crystal display of claim 17, further comprising:
forming inlets of the plurality of microcavities between the partition walls and the roof layer.

19. The manufacturing method of a liquid crystal display of claim 18, wherein:
the light blocking material layer has negative photo characteristics.

20. The manufacturing method of a liquid crystal display of claim 19, wherein:
exposure wavelengths in the exposing of the preliminary partition wall region and in the patterning of the roof material layer by the photo process to form the roof layer are different from each other.
